(19) United States
(12) Patent Application Publication
(10) Pub. No.: US 2013/0099254 A1
(43) Pub. Date: Apr. 25, 2013

(54) LIGHT EMITTING DIODE WITH CHAMFERED TOP PERIPHERAL EDGE

(71) Applicants: TZU-CHIEN HUNG, Hsinchu (TW); CHIA-HUI SHEN, Hsinchu (TW); CHIEN-CHUNG PENG, Hsinchu (TW)

(72) Inventors: TZU-CHIEN HUNG, Hsinchu (TW); CHIA-HUI SHEN, Hsinchu (TW); CHIEN-CHUNG PENG, Hsinchu (TW)

(73) Assignee: ADVANCED OPTOELECTRONIC TECHNOLOGY, INC., Hsinchu Hsien (TW)

(21) Appl. No.: 13/563,737

(22) Filed: Aug. 1, 2012

(30) Foreign Application Priority Data
Oct. 19, 2011 (CN) 201110318277.5

(51) Int. Cl. H01L 33/20

(52) U.S. Cl. 257/79; 257/E33.006

(57) ABSTRACT

A light emitting diode includes a substrate and a light emitting structure. The light emitting structure includes a light outputting surface away from the substrate and a plurality of sidewalls adjoining the light outputting surface. A top peripheral edge interconnecting the light outputting surface and the sidewalls of the light emitting structure is a rounded top peripheral edge or a beveled top peripheral edge. A top surface of the substrate surrounding the light emitting structure is exposed to air and formed with micro-structures.

### BACKGROUND

1. Technical Field

The disclosure relates to light emitting diodes, and particularly to a light emitting diode with a chamfered top peripheral edge on the light outputting surface, to thereby increase the light extraction efficiency of the light emitting diode.

2. Description of the Related Art

A conventional light emitting diode (LED) includes a substrate, a light emitting structure having an N-type semiconductor layer, an active layer and a P-type semiconductor layer formed on the substrate in sequence, and two electrodes (i.e., N-type and P-type electrodes) respectively connected to the N-type and P-type semiconductor layers.

Generally, the light emitting structure includes a light outputting surface and four lateral sidewalls adjoining the light outputting surface. The light outputting surface is usually configured horizontally on a top of the light emitting structure and away from the substrate, and the sidewalls are usually configured vertically at lateral sides of the light emitting structure. In other words, the light outputting surface intersects the four sidewalls perpendicularly. Referring to FIG. 5, a light path diagram of a conventional light emitting diode 1 is illustrated. A light beam emitted from the active layer 3, which is represented by arrow A travels to the vertical sidewall 2 of the light emitting structure. The light beam A, which intersects the active layer 3 at an angle γ, strikes the sidewall 2 at an incident angle α equal to the angle γ. When the angle γ is larger than a critical angle, a total internal reflection will unfavorably occur. Accordingly, the light extraction efficiency of the light emitting diode is decreased.

Therefore, it is desirable to provide a light emitting diode with high light extraction efficiency.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode and a method for manufacturing the light emitting diode. Moreover, in the drawings, like reference numerals designate corresponding parts throughout the views.

FIG. 1 is a schematic, top view of a light emitting diode in accordance with a first exemplary embodiment of the present disclosure.

FIG. 2 is a schematic, cross-sectional view of the light emitting diode of FIG. 1, taken along line II-II thereof.

FIG. 3 is a light path diagram of the light emitting diode of FIG. 1.

FIG. 4 is a schematic, cross-sectional view of a light emitting diode in accordance with a second exemplary embodiment of the present disclosure.

FIG. 5 is a light path diagram of a conventional light emitting diode.

### DETAILED DESCRIPTION

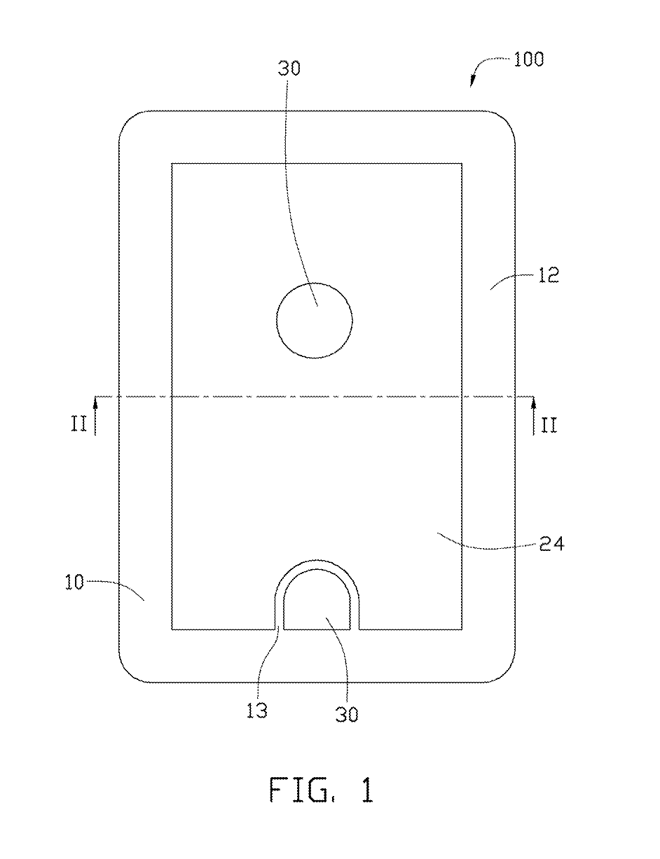

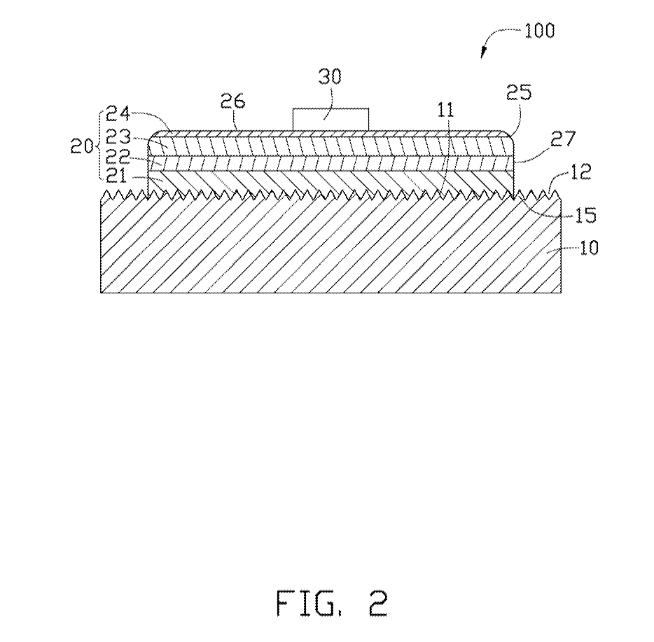

Referring to FIGS. 1 and 2, a light emitting diode 100 in accordance with a first exemplary embodiment is provided. The light emitting diode 100 includes a substrate 10, a light emitting structure 20 grown on the substrate 10, and two electrodes 30.

The substrate 10 is dielectric and patterned. The substrate 10 includes an upper surface 11 with a patterned structure thereon. The patterned structure preferably includes a plurality of micro-structures 15. Each micro-structure 15 preferably is a protrusion on the upper surface 11. The substrate 10 can be rectangular or circular. In this embodiment, the substrate 10 is rectangular. The substrate 10 can be sapphire (α-Al₂O₃) substrate, silicon carbide (SiC) substrate, etc.

The light emitting structure 20 is formed on the upper surface 11 of the substrate 10. The light emitting structure 20 covers a part of the upper surface 11. The other part of the upper surface 11, which is exposed outside, is defined as a cutting passage 12. The cutting passage 12 surrounds the light emitting structure 20. There is a plurality of micro-structures 15 formed on the upper surface 11 of the substrate 10. The light emitting structure 20 defines a recessed electrode area 13 accommodating one of the electrodes 30 (FIG. 1). The other electrode 30 is formed on a top of the light emitting structure 20. The upper surface 11 of the substrate 10 is substantially covered by the light emitting structure 20 in total, except the area where the cutting passage 12 is formed. The cutting passage 12 is formed by inductively coupled plasma dry etching. That is, a part of the light emitting structure 20 originally covering the cutting passage 12 is removed by inductively coupled plasma dry etching to expose the micro-structures 15 at the cutting passage 12 to air. The micro-structures 15 are partly covered by the light emitting structure 20. The other micro-structures 15 which are formed at the cutting passage 12 are exposed to air.

An area of the cutting passage 12 is about 5%˜25% of a total area of the upper surface 11 of the substrate 10. Should the cutting passage 12 be covered by the light emitting structure 20 as practiced in prior art, due to the total internal reflection of light emitting structure 20, light extraction efficiency is low. According to the present disclosure, the micro-structures 15 at the cutting passage 12 is exposed to air, whereby the cutting passage 12 can help refraction and reflection of the light out of the light emitting diode 100; thus, a light extraction efficiency according to the present disclosure is promoted.

The light emitting structure 20 includes a first-type semiconductor layer 21, an active layer 22, a second-type semiconductor layer 23, and a transparent conductive layer 24 formed on the substrate 10 in sequence from bottom to top. The electrode 30 in the electrode area 13 is in electrically connection with the first-type semiconductor layer 21. The electrode 30 on the top of the light emitting structure 20 is in electrical connection with the transparent conductive layer 24. In other words, the first-type semiconductor layer 21 is formed on the substrate 10 directly. The active layer 22 is sandwiched between the first-type semiconductor layer 21 and the second-type semiconductor layer 23. The first-type semiconductor layer 21, the active layer 22 and the second-type semiconductor layer 23 can be made of III-V or II-VI compound semiconductors. The first-type semiconductor layer 21 and the second-type semiconductor layer 23 are doped with different materials. In this embodiment, the first-type semiconductor layer 21 is N-type doped, and the second-type semiconductor layer 23 is P-type doped. In alternative embodiment, the first-type semiconductor layer 21 can be P-type doped, and the second-type semiconductor layer 23 can be N-type doped. Alternatively, a buffer layer (not shown) made of GaN or AlN can be grown on the substrate 10 before the first-type semiconductor layer 21 is formed on the substrate 10 to improve the quality of growth of the first-type semiconductor layer 21 on the substrate 10.

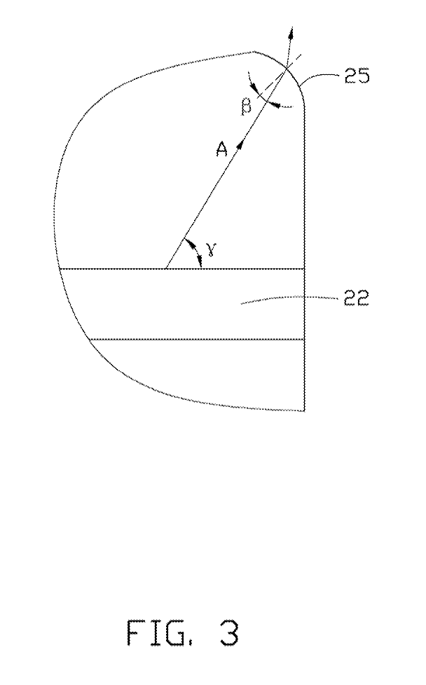

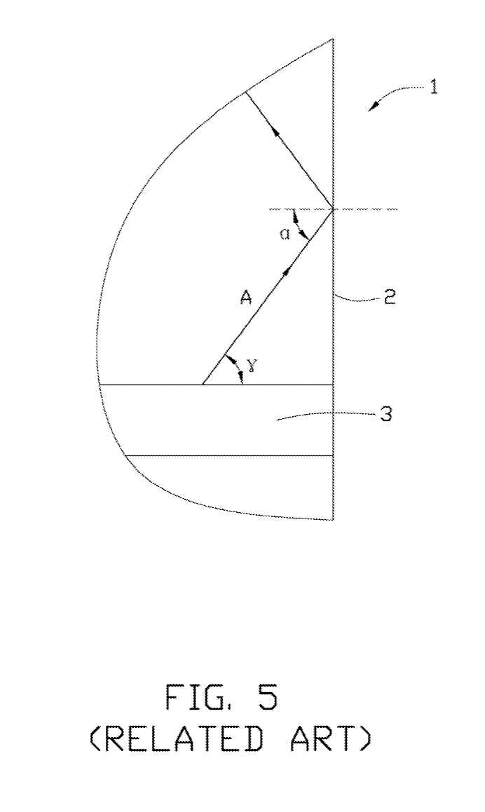

Also referring to FIG. 3, the light emitting structure 20 includes a light outputting surface 26 and four sidewalls 27 adjoining the light outputting surface 26. In this embodiment, the light outputting surface 26 is configured horizontally on top of the light emitting structure 20 and away from the substrate 10. A top peripheral edge 25 is formed for connecting the light outputting surface 26 and the four sidewalls 27. The top peripheral edge 25 is chamfered as a rounded top peripheral edge. The top peripheral edge 25 extends from a periphery of the light outputting surface 26 to an upper part of lateral sidewalls of the second-type semiconductor layer 23 to thereby interconnect the light outing surface 26 and the four sidewalls 27 of the light emitting structure 20. A light beam A generated by the active layer 22 strikes the top peripheral edge 25 between the light outputting surface 26 and the sidewall 27 of the light emitting structure 20. An angle γ is formed between the light beam A and the active layer 22. The light beam A strikes the top peripheral edge 25 at an incident angle β. Since the top peripheral edge 25 is rounded, the incident angle β is smaller than the incident angle α of the conventional light emitting diode 1 of FIG. 5 which is equal to the angle γ. The reduction of the incident angle at the top peripheral edge 25 of the light emitting diode 100 according to the present disclosure greatly reduces a total internal reflection in the light emitting structure 20. The light beam A can travel out of the light emitting structure 20 though the top peripheral edge 25 more easily, thereby increasing the light extraction efficiency of the light emitting diode 100.

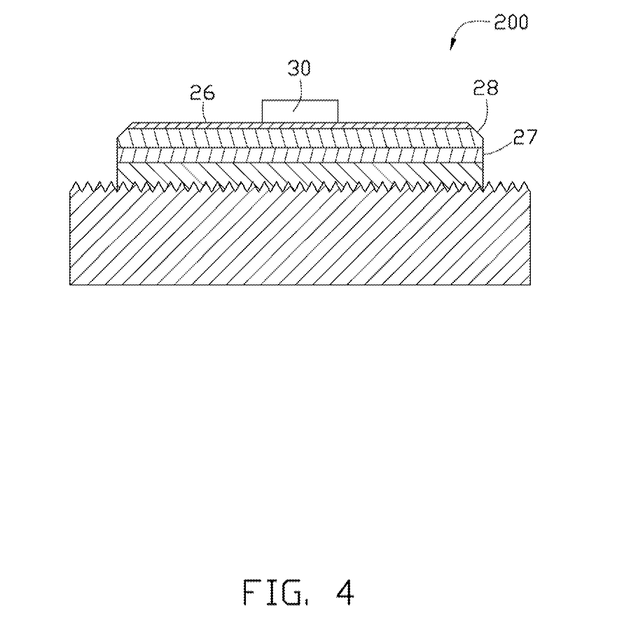

Referring to FIG. 4, a light emitting diode 200 in accordance with a second exemplary embodiment is provided. The differences between the light emitting diode 200 and the light emitting diode 100 are described below. In this embodiment, a top peripheral edge 28 which interconnecting the light outputting surface 26 and the four sidewalls 27 is chamfered as a beveled top peripheral edge. The chamfered peripheral edge 28 can avoid a vertical intersection between the top surface 26 and the four sidewalls 27 to reduce an incident angle of a light beam on the top peripheral edge for avoiding a total reflection.

The present disclosure provides a round-chamfered or a bevel-chamfered top peripheral edge 25, 28 to connect the light outputting surface 26 and the four sidewalls 27, thereby reducing a total internal reflection and increasing a light extraction efficiency thereof. The area of the cutting passage 12 is about 5%˜25% of the substrate 10 to increase utilization of the substrate 10 in the refraction and reflection of the light beam generated by the active layer 22 out of the light emitting diode 100, 200. Accordingly, light extraction efficiency according to the present disclosure can be increased significantly.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode, comprising:
a substrate; and
a light emitting structure comprising a light outputting surface away from the substrate and a plurality of sidewalls adjoining the light outputting surface;
wherein a top peripheral edge interconnecting the light outputting surface and the sidewalls of the light emitting structure is chamfered.

2. The light emitting diode of claim 1, wherein the top peripheral edge is chamfered to be one of a rounded top peripheral edge or a beveled top peripheral edge.

3. The light emitting diode of claim 2, wherein the light outputting surface is configured horizontally on a top of the light emitting structure and away from the substrate.

4. The light emitting diode of claim 2, wherein the light emitting structure comprises a first-type semiconductor layer formed on the substrate, an active layer formed on the first-type semiconductor layer, and a second-type semiconductor layer formed on the active layer.

5. The light emitting diode of claim 4, wherein the top peripheral edge extends to lateral sidewalls of the second-type semiconductor layer.

6. The light emitting diode of claim 5, wherein the light emitting structure further comprises a transparent, electrically conductive layer on the second-type semiconductor layer, and the top peripheral edge extends from a periphery of the transparent, electrically conductive layer to the lateral sidewalls of the second-type semiconductor layer.

7. The light emitting diode of claim 2, wherein the substrate comprises an upper surface, the light emitting structure covers a central part of the upper surface, and the other part of the upper surface which surrounds the light emitting structure is exposed to air, the substrate having a patterned structure on the upper surface thereof.

8. The light emitting diode of claim 7, wherein an area of the other part of the upper surface of the substrate is substantially 5%˜25% of a total area of the upper surface of the substrate.

9. The light emitting diode of claim 7, wherein the patterned structure includes a plurality of micro-structures formed on the upper surface of the substrate.

10. The light emitting diode of claim 7, wherein a part of the light emitting structure is recessed to accommodate an electrode.

11. The light emitting diode of claim 4, wherein the first-type semiconductor layer is an N-type semiconductor layer and the second-type semiconductor layer is a P-type semiconductor layer.

12. A light emitting diode, comprising:
a substrate; and
a light emitting structure comprising a top surface away from the substrate, at least one sidewall, and a top peripheral edge interconnecting the top surface and the at least one sidewall, the top peripheral edge being chamfered to be one of a rounded top peripheral edge and a beveled top peripheral edge.

13. The light emitting diode of claim 12, wherein the light emitting structure comprises a first-type semiconductor layer formed on the substrate, an active layer formed on the first-type semiconductor layer, and a second-type semiconductor layer formed on the active layer.

14. The light emitting diode of claim 13, wherein the top peripheral edge extends to a lateral sidewall of the second-type semiconductor layer.

15. The light emitting diode of claim 14, wherein the light emitting structure further comprises a transparent, electrically conductive layer formed on the second-type semiconductor layer, and the top peripheral edge extends from a periphery of the transparent, electrically conductive layer to the lateral sidewall of the second-type semiconductor layer.

16. The light emitting diode of claim 12, wherein the substrate comprises an upper surface, the light emitting structure covers a part of the upper surface, and the other part of the upper surface is exposed to air.

17. The light emitting diode of claim 16, wherein an area of the other part of the upper surface is substantially 5%˜25% of a total area of the upper surface of the substrate.

18. The light emitting diode of claim 16, wherein a plurality of micro-structures is formed on the other part of the upper surface of the substrate and the other part of the upper surface of the substrate surrounds the light emitting structure.

19. A light emitting diode, comprising:
a substrate having an upper surface; and
a light emitting structure formed on a central part of the upper surface of the substrate, the light emitting structure comprising a top surface away from the substrate and at least one side surface adjoining the top surface, the at least one side surface at a top end of the light emitting structure being configured to be one of being round-chamfered and bevel-chamfered;
wherein a peripheral part of the upper surface of the substrate which has an area 5%˜25% of a total area of the upper surface of the substrate is exposed to air and formed with a plurality of micro-structures thereon.

20. The light emitting diode of claim 19, wherein the light emitting structure comprises a first-type semiconductor layer formed on the substrate, an active layer formed on the first-type semiconductor layer, a second-type semiconductor layer formed on the active layer, and a transparent, electrically conductive layer formed on the second-type semiconductor layer, and a periphery of the transparent, electrically conductive layer and an upper part of lateral wall of the second-type semiconductor layer together are configured to be one of being round-chamfered and bevel-chamfered.
